(19) United States
(12) Patent Application Publication
(10) Pub. No.: US 2016/0196923 A1
(43) Pub. Date: Jul. 7, 2016

(54) ELECTROSTATIC DAMPING OF MEMS DEVICES

(71) Applicant: CAVENDISH KINETICS, INC, San Jose, CA (US)

(72) Inventors: Robertus Petrus VAN KAMPEN, S-Hertogenbosch (NL); Anartz UNAMUNO, Dresden (DE)

(21) Appl. No.: 14/889,629

(22) PCT Filed: May 20, 2014
(86) PCT No.: PCT/US14/38771

§ 371 Date: Nov. 6, 2015

Related U.S. Application Data
(60) Provisional application No. 61/826,063, filed on May 22, 2013.

(51) Int. Cl. H01G 5/18; B81B 7/00

(52) U.S. Cl. CPC H01G 5/18; B81B 7/008; B81B 2201/0221

(57) ABSTRACT

The present invention generally relates to a method and apparatus for damping a plate electrode or switching element in a MEMS DVC device. A resistor disposed between a waveform controller and the electrodes of the MEMS DVC causes the voltage to increase while capacitance decreases during the time that the plate electrode is moving. Due to the increase in voltage and decrease in capacitance, the electrostatic force that resists the plate electrode movement away from an electrode increases, which in turn dampens the movement of the plate electrode.

### BACKGROUND OF THE INVENTION

1. Field of the Invention

Embodiments of the present invention generally relate to a method and apparatus for damping a plate electrode in a micro-electromechanical system (MEMS) digital variable capacitor (DVC) device.

2. Description of the Related Art

A DVC device operates with electrostatic forces. In this mechanism a force is acting on the moveable MEMS element when a voltage V is applied between the plate or switching electrode and a control electrode. The electrostatic force scales with (V/gap)². The mechanical counter-balance force comes from a spring suspension system and typically scales linearly with the displacement. The result is that with an increasing voltage V the MEMS device moves a certain distance 6 toward the control-electrode. This movement reduces the gap which in turn increases the electrostatic force further. For small voltages, an equilibrium position between the initial position and the electrode is found. However, when the voltage exceeds a certain threshold level (i.e., the pull-in voltage), the device displacement is such that the electrostatic force rises faster than the mechanical counterbalance force and the device rapidly snaps-in (i.e., moves) towards the control-electrode until it comes in contact.

Some DVC devices have a control-electrode above (i.e., a pull-up or pull-off or PU-electrode) and below (i.e., a pull-down or pull-in or PD-electrode) the moveable MEMS device (i.e., the plate in FIG. 1), as shown schematically in FIG. 1. In addition there is an RF-electrode below the moveable MEMS device. During operation the MEMS device is either pulled-up or pulled-down in contact to provide a stable minimum or maximum capacitance to the RF-electrode. In this way the capacitance from the moveable element to the RF-electrode (which resides below the moveable element) can be varied from a high capacitance Cₘₐₓ when pulled to the bottom, as shown in FIG. 2, to a low capacitance Cₘᵢₙ when pulled to the top, as shown in FIG. 3.

The voltages applied to the PD-electrode (Vbottom) and to the PU-electrode (Vtop) are typically controlled by a waveform controller, as shown in FIG. 4, to ensure a long-life stable performance of the DVC device. The moveable element is typically on DC-ground. The variable capacitors (i.e., Cpd, Cpu) represent the capacitances of the pull-down and pull-up electrodes respectively of a MEMS DVC device.

FIG. 5 shows the control-voltages and MEMS dynamic response when switching from the Cₘₐₓ state to the Cₘᵢₙ state. The MEMS DVC device is initially landed on the bottom by a control-voltage Vbottom=HV and Vtop=0V. At t=t0 the bottom voltage is released (Vbottom=0V) and the top-voltage Vtop is slowly ramped from 0 to HV. As soon as the device is released from the bottom electrode it freely rings while the top control-voltage is being ramped.

The rate at which the ringing dies out depends on the Q of the MEMS device which is related to pressure inside the cavity (squeeze-film damping) and losses inside the MEMS device itself. The device pulls-in to the top-electrode at t=t1 when the voltage has reached the required pull-in voltage level. The voltage continues to ramp and has reached its final value at t=t2. When the ramp-rate of the control voltage is increased, the MEMS device will switch to the other-state faster, as shown in FIG. 6.

In this case, the MEMS element will hit the pull-electrode while the transient ringing of the free-moving MEMS element has not died out yet and depending on the actual time of impact it can hit the contact surface at considerable speeds such that the contact interface suffers from mechanical damage which may lead to early lifetime failures.

Therefore, there is a need in the art for a MEMS DVC device in which the plate electrode of the MEMS DVC device has less ringing/vibration during the state transition.

### SUMMARY OF THE INVENTION

The present invention generally relates to a method and apparatus for damping a plate electrode or switching element in a MEMS DVC device. A resistor disposed between a waveform controller and the electrodes of the MEMS DVC causes the voltage to increase while capacitance decreases during the time that the plate electrode is moving. Due to the increase in voltage and decrease in capacitance, the electrostatic force that resists the plate electrode movement away from an electrode increases, which in turn dampens the movement of the plate electrode.

In one embodiment, a device comprises a MEMS device, a waveform controller and a first resistor. The MEMS device comprises a plate electrode; the first electrode; a first dielectric layer disposed over the first electrode; a second electrode disposed opposite the first electrode; and a second dielectric layer disposed over the second electrode such that the plate electrode is movable between a first position in contact with the first dielectric layer, a second position in contact with the second dielectric layer, and a third position spaced from both the first and second dielectric layers. The waveform controller is coupled to the first electrode and the second electrode. The first resistor is coupled between the first electrode and the waveform controller.

In another embodiment, a method of operating a MEMS device comprises reducing a voltage applied to a first electrode of the MEMS device to zero, wherein the MEMS device comprises the first electrode, a second electrode and a plate electrode movable from a first position disposed adjacent the first electrode and a second position disposed adjacent the second electrode. The method also comprises reducing a capacitance of the first electrode; applying a voltage to the second electrode while reducing the capacitance of the first electrode; increasing the voltage applied to the second electrode; moving the plate electrode from the first position to the second position; increasing a capacitance of the second electrode during the moving; and decreasing the capacitance of the first electrode during the moving.

In another embodiment, a method of operating a MEMS device comprises reducing a voltage applied to a first electrode of the MEMS device to zero, wherein the MEMS device comprises the first electrode, a second electrode and a plate electrode movable from a first position disposed adjacent the first electrode and a second position disposed adjacent the second electrode. The method also comprises discharging the voltage applied to the first electrode through a first resistor; applying a voltage to the second electrode while discharging the voltage; increasing a capacitance of the second electrode; and decreasing the capacitance of the first electrode, wherein the increasing and decreasing occurs while increasing the voltage applied to the second electrode.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional illustration of a MEMS DVC in the free standing state.

FIG. 2 is a schematic cross-sectional illustration of the MEMS DVC of FIG. 1 in the Cₘₐₓ state.

FIG. 3 is a schematic cross-sectional illustration of the MEMS DVC of FIG. 1 in the Cₘᵢₙ state.

FIG. 4 is a schematic illustration of a waveform controller driving a MEMS DVC device.

FIG. 5 shows graphs illustrating the dynamic behavior of a MEMS DVC device when switching from the Cₘₐₓ state to the Cₘᵢₙ state.

FIG. 6 shows graphs illustrating the dynamic behavior when switching from the Cₘₐₓ state to the Cₘᵢₙ state at a speed that is faster than shown in FIG. 5.

FIG. 7 is a schematic illustration of a waveform controller coupled to a MEMS DVC according to one embodiment.

FIG. 8 shows graphs illustrating a MEMS DVC pull-in with electrostatic damping.

FIG. 9 shows graphs illustrating a MEMS DVC pull-in with electrostatic damping when the pull-in occurs faster than exemplified in FIG. 8.

FIG. 10 shows graphs illustrating the impact speed comparison of a MEMS DVC with and without electrostatic damping.

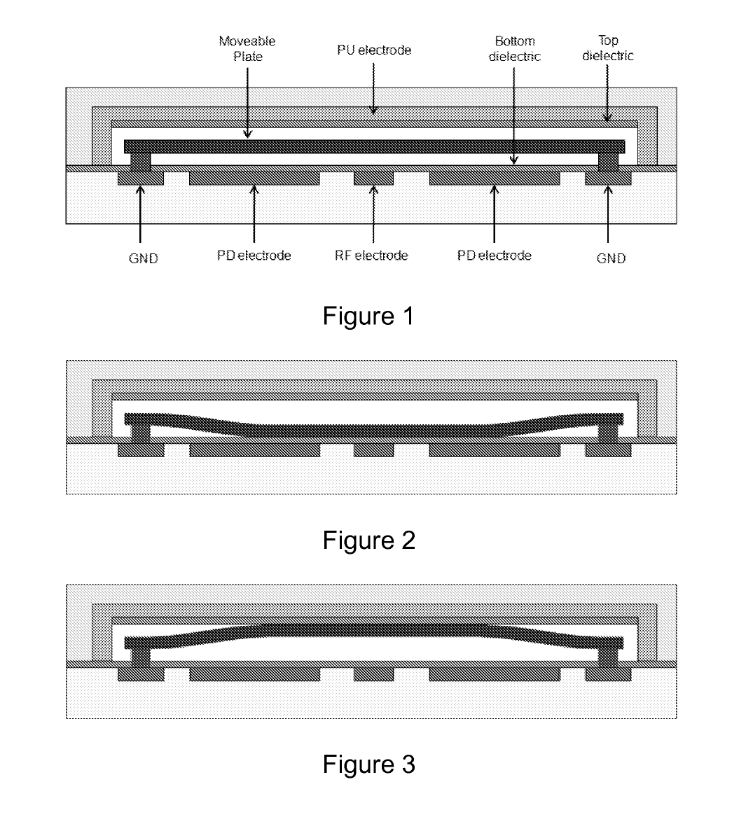

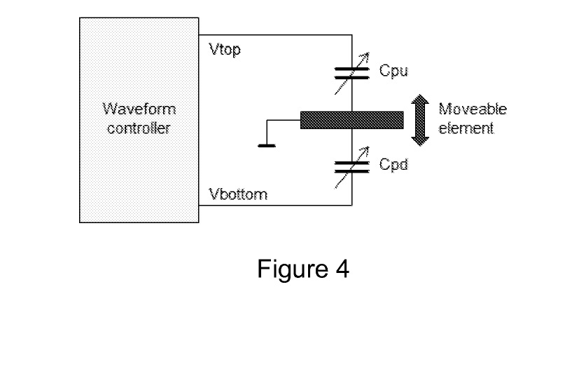

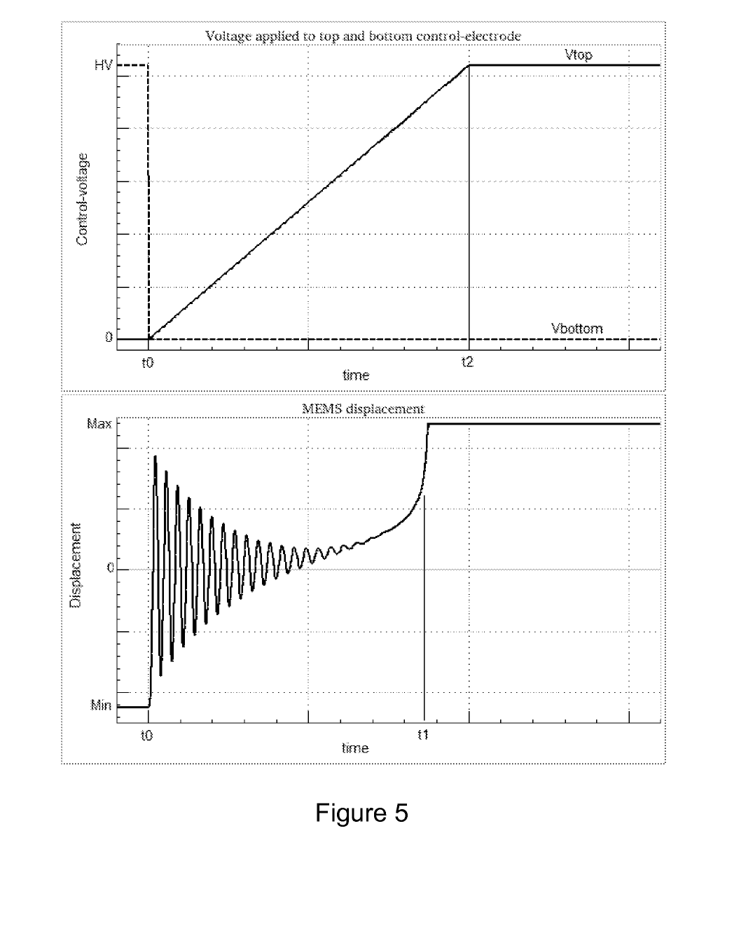

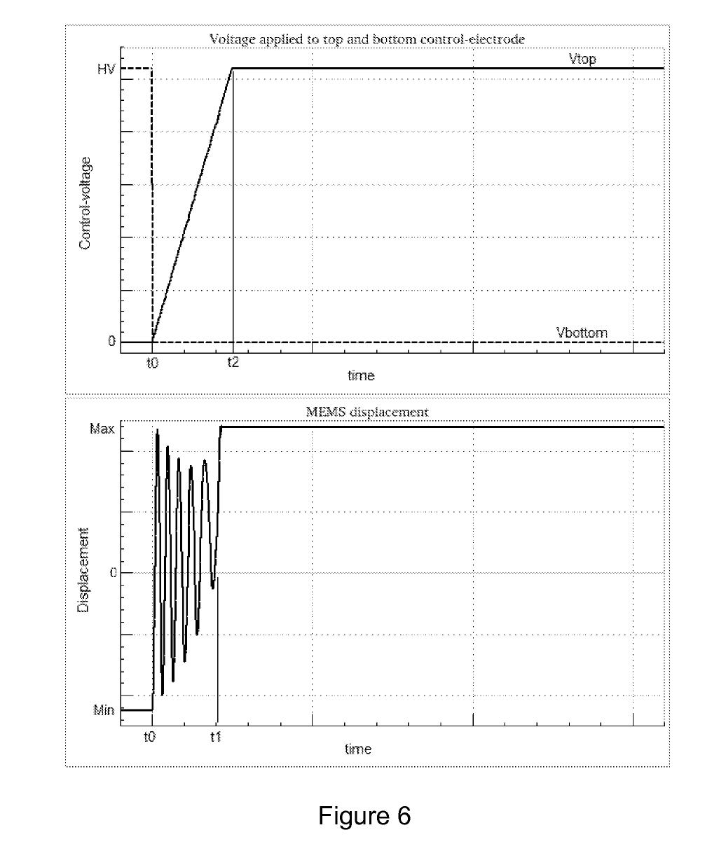

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally relates to a method and apparatus for damping a plate electrode or switching element in a MEMS DVC device. A resistor disposed between a waveform controller and the electrodes of the MEMS DVC causes the voltage to increase while capacitance decreases during the time that the plate electrode is moving. Due to the increase in voltage and decrease in capacitance, the electrostatic force that resists the plate electrode movement away from an electrode increases, which in turn dampens the movement of the plate electrode.

As described herein, the method and technique reduce the damping of the MEMS device by means of electrostatic forces in a self-contained way. The method and device described herein increases the damping of the MEMS device which ensures that the transient behavior of the MEMS element during a state transition die out faster. This allows the ramp-rate of the control-voltage to be increased leading to faster switching times. Additionally, the impact speed upon landing is decreased which results in an increased MEMS lifetime performance.

When the plate electrode moves, the capacitance between the plate electrode and the control electrode (i.e., pull-up or pull-down electrode) is modulated. As a result, the current flowing though the control-capacitor is given by:

$$i = \frac{dQ}{dt} = \frac{d ( C * V )}{dt} = C * \frac{dV}{dt} + V * \frac{dC}{dt}$$

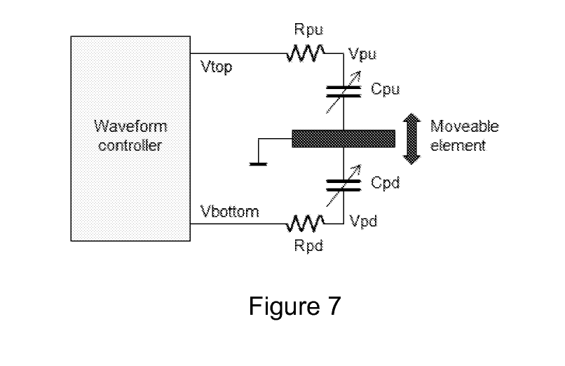

Thus, there is a component in the current through the capacitor that is proportional to dC/dt (i.e., proportional to the velocity of the plate electrode). By adding a resistor in series with the control capacitor (See FIG. 7) the current can be converted into a voltage (Vpu or Vpd) which will then provide electrostatic forces acting on the plate electrode.

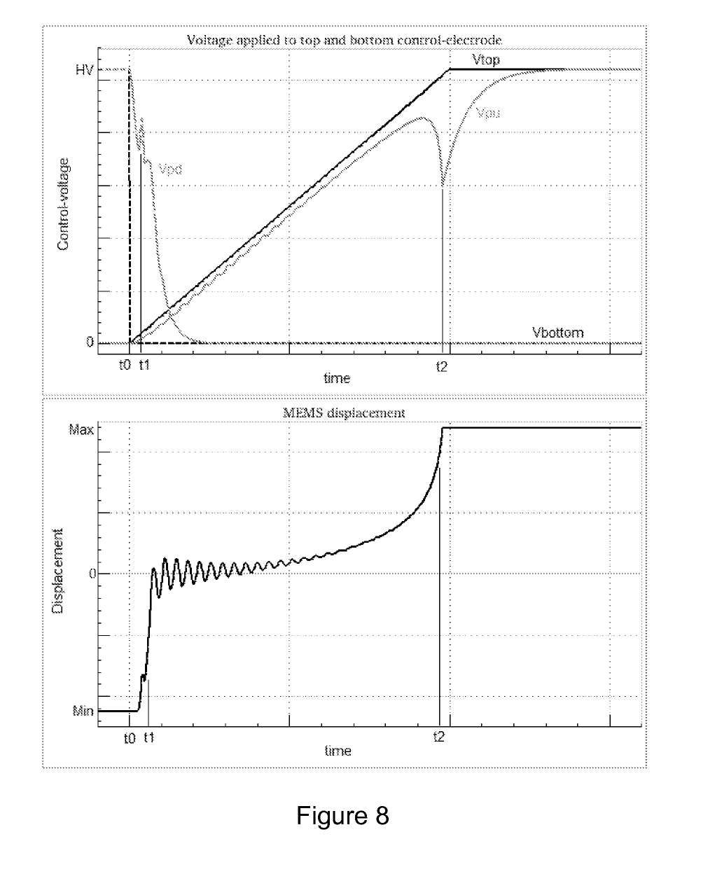

The electrostatic forces are thus providing for a means of damping (‘electrostatic damping’). This is illustrated in FIG. 8, where at t=t0, the bottom control voltage is set to Vbottom=0. However, the voltage on the actual capacitance Vpd does not immediately drop to 0, because the Cbottom needs to be discharged through Rpd. As the voltage drops, the electrostatic force holding the MEMS element down decreases. At t=t1, the electrostatic force is lower than the mechanical restoring force and the MEMS element is released from the bottom.

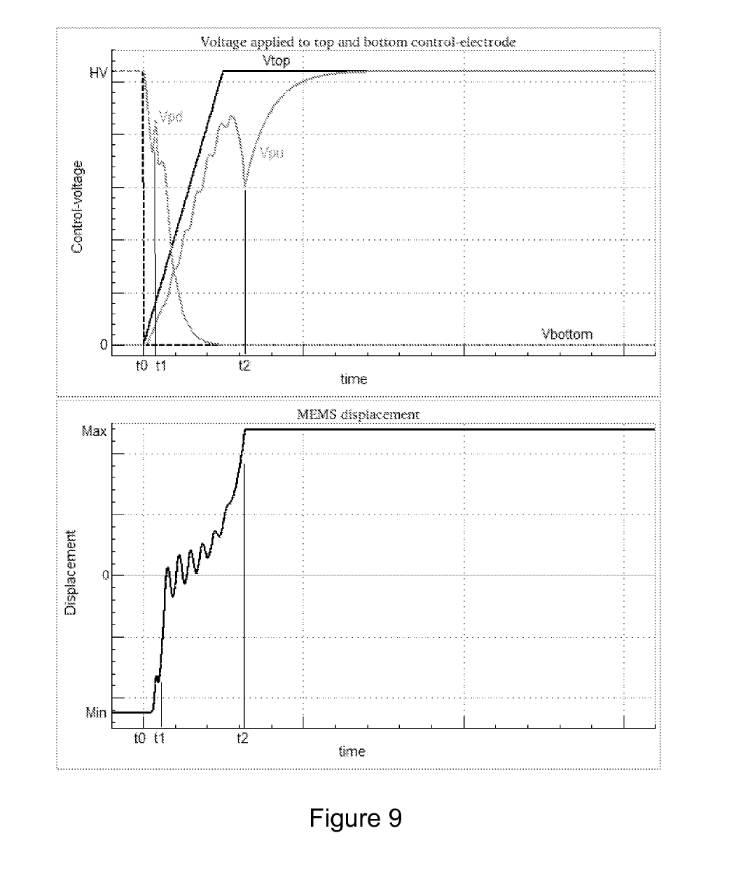

The capacitance quickly reduces, and if the resistor is sufficiently large so that Rpd*Cpd is larger than the actual dynamic response time of the plate electrode, then no charge can be added to or removed from Cpd (i.e., the total charge Qpd on Cpd remains constant). Since Qpd=Cpd*Vpd, as Cpd decreases, Vpd increases. The increase in Vpd provides an increase in electrostatic force which resists the plate electrode's movement away from the electrode. The end result is that the device motion is damped as the plate electrode moves away from the control electrode, which facilitates the use of a fast ramp (See FIG. 9).

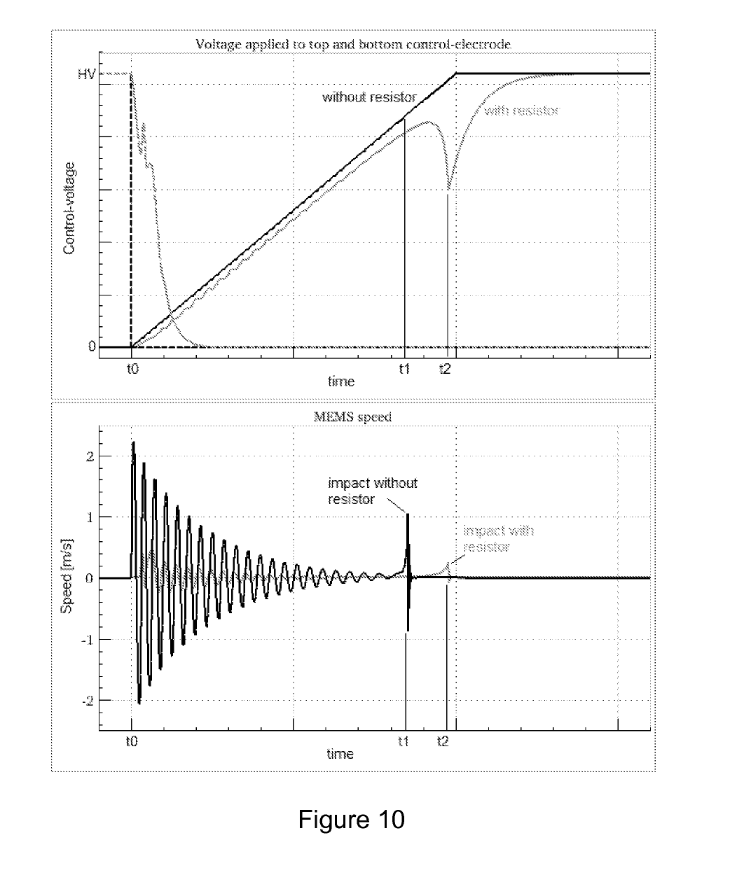

A second advantage of the electrostatic damping method is a reduced impact speed as the plate electrode hits the dielectric layer covering the control electrode, as shown in FIG. 10. When the resistor is added, the voltage on the capacitor drops when the device snaps in due to the sudden increase in the capacitor value (C*V=constant). As a result there is less electrostatic force pulling the plate electrode into contact, resulting in a reduced impact speed.

While the foregoing is directed to embodiments of the present invention, other and further embodiments of the invention may be devised without departing from the basic scope thereof, and the scope thereof is determined by the claims that follow.

1. A device, comprising:
a MEMS device comprising:
a plate electrode;
the first electrode;
a first dielectric layer disposed over the first electrode;
a second electrode disposed opposite the first electrode; and
a second dielectric layer disposed over the second electrode such that the plate electrode is movable between a first position in contact with the first dielectric layer, a second position in contact with the second dielectric layer, and a third position spaced from both the first and second dielectric layers;
a waveform controller coupled to the first electrode and the second electrode; and
a first resistor coupled between the first electrode and the waveform controller.

2. The device of claim 1, further comprising a second resistor coupled between the second electrode and the waveform controller.

3. The device of claim 2, wherein the resistance of the second resistor times the capacitance of the second electrode is larger than the dynamic response time of the plate electrode.

4. The device of claim 2, wherein the resistance of the first resistor times the capacitance of the first electrode is larger than a dynamic response time of the plate electrode.

5. The device of claim 4, wherein the resistance of the second resistor times the capacitance of the second electrode is larger than the dynamic response time of the plate electrode.

6. The device of claim 1, wherein the resistance of the first resistor times the capacitance of the first electrode is larger than a dynamic response time of the plate electrode.

7. A method of operating a MEMS device, comprising:
reducing a voltage applied to a first electrode of the MEMS device to zero, wherein the MEMS device comprises the first electrode, a second electrode and a plate electrode movable from a first position disposed adjacent the first electrode and a second position disposed adjacent the second electrode;
reducing a capacitance of the first electrode;
applying a voltage to the second electrode, wherein the voltage is applied to the second electrode either:
while reducing the capacitance of the first electrode; or
after the capacitance of the first electrode has decreased;
increasing the voltage applied to the second electrode;
moving the plate electrode from the first position to the second position;
increasing a capacitance of the second electrode during the moving; and
decreasing the capacitance of the first electrode during the moving.

8. The method of claim 7, wherein the plate electrode vibrates during the moving.

9. The method of claim 8, wherein the vibrating decreases as the plate electrode moves from the first position to the second position.

10. The method of claim 9, wherein during the reducing the capacitance of the first electrode, the voltage applied to the first electrode increases and wherein electrostatic force at the plate electrode increases while the voltage applied to the first electrode increases.

11. The method of claim 7, wherein applying the voltage to the second electrode occurs while the reducing the capacitance of the first electrode, and wherein the voltage applied to the first electrode increases.

12. The method of claim 11, wherein electrostatic force at the plate electrode increases while the voltage applied to the first electrode increases.

13. The method of claim 7, wherein applying the voltage to the second electrode occurs after the capacitance of the first electrode has discharged, and wherein the voltage applied to the first electrode increases.

14. A method of operating a MEMS device, comprising:
reducing a voltage applied to a first electrode of the MEMS device to zero, wherein the MEMS device comprises the first electrode, a second electrode and a plate electrode movable from a first position disposed adjacent the first electrode and a second position disposed adjacent the second electrode;
discharging the voltage applied to the first electrode through a first resistor;
applying a voltage to the second electrode, wherein the voltage is applied to the second electrode either:
while discharging the voltage to the first electrode; or
after the capacitance of the first electrode has decreased;
increasing a capacitance of the second electrode; and
decreasing the capacitance of the first electrode, wherein the increasing and decreasing occurs while increasing the voltage applied to the second electrode.

15. The method of claim 14, wherein the plate electrode vibrates during the reducing, discharging, applying, increasing and decreasing.

16. The method of claim 15, wherein the vibrating decreases as the plate electrode moves from the first position to the second position.

17. The method of claim 16, wherein during the reducing the discharging, the voltage applied to the first electrode increases and wherein electrostatic force at the plate electrode increases while the voltage applied to the first electrode increases.

18. The method of claim 14, wherein during the reducing the discharging, the voltage applied to the first electrode increases.

19. The method of claim 18, wherein electrostatic force at the plate electrode increases while the voltage applied to the first electrode increases.

20. The method of claim 14, wherein applying the voltage to the second electrode occurs after the capacitance of the first electrode has discharged, and wherein the voltage applied to the first electrode increases.
